(19) United States
(12) Patent Application Publication
(10) Pub. No.: US 2005/0245052 A1
(43) Pub. Date: Nov. 3, 2005

(54) Semiconductor device having a gettering layer

(75) Inventor: Yasukazu Inoue, Tokyo (JP)

Correspondence Address: MCGINN & GIBB, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 11/115,327

(22) Filed: Apr. 27, 2005

(30) Foreign Application Priority Data
Apr. 28, 2004 (JP) 2004-133383

(51) Int. Cl. H01L 21/44; H01L 21/48; H01L 21/30

(52) U.S. Cl. 438/476; 438/471; 438/459; 438/310; 438/115

(57) ABSTRACT

A multi-chip-package (MCP) module includes a plurality of semiconductor chips layered one on another. The lower semiconductor chip includes a semiconductor substrate having a top active layer and a bottom heavily-doped layer. The bottom of the heavily-doped layer is polished twice by a rough-polishing treatment and a mirror-polishing treatment. The thickness of the impurity-doped layer is not less than 50% of the thickness of the semiconductor substrate which is not larger than 130 μm.

### BACKGROUND OF THE INVENTION

1. Field of the Invention

The present invention relates to a semiconductor device having a gettering layer and a method for manufacturing the same. More particularly, the present invention relates to a semiconductor device having a gettering layer in a small-thickness substrate for use as a semiconductor chip in a multi-chip-package (MCP) system, and also to a method for manufacturing such a semiconductor device.

2. Description of the Related Art

Any semiconductor device provided in the form of a semiconductor chip generally has a problem in that incoming heavy metals mixed in the semiconductor substrate or attached onto the surfaces of the device diffuse to the vicinity of the element active region during heat treatments performed in the process of manufacturing the semiconductor device. To suppress the degradation in the reliability of the semiconductor device caused by the heavy metals, a variety of measures have been employed heretofore. For example, a cleaning process is carried out between fabrication steps in the process for manufacturing the semiconductor device, thereby preventing heavy metals from being attached onto the semiconductor device. Alternatively, heavy metals are confined outside the element active region, by forming a gettering layer around the element active region, in order to control the diffusion of the heavy metals from the substrate.

A variety of types of gettering layers have been used in the art. Jpn. Pat. Appln. Laid-Open Publication Nos. 11-135510 and 11-145146, for example, describe gettering layers in which inter-lattice oxygen is precipitated and which therefore has a large number of crystal defects. In this layer, the crystal defects resulting from the oxygen precipitation perform a gettering function.

In recent years, it has been demanded that portable apparatuses such as cellular telephones and digital still cameras (DSCs) be made smaller. To meet the demand, MCP modules are used because the MCP modules include therein a large number of semiconductor devices laid one on another and therefore have a higher integration density.

FIG. 5 shows an example of the MCP module of BGA (Ball Grid Array) structure, in which two semiconductor chips are arranged, one on the other. In the MCP module 30, the lower semiconductor chip 13 is adhered onto the MCP substrate 11, by using an adhesive layer 12. A surface protective film 14 is provided on top of the lower semiconductor chip 13. An adhesive layer 15 is laid on the surface protective film 14. The upper semiconductor chip 16 is mounted on the adhesive layer 15. Interconnections are provided within the MCP substrate 11. The lower semiconductor chip 13 has an element active region 13a in the top surface region thereof. Similarly, the upper semiconductor chip 16 has an element active region 16a in the top surface region thereof. The MCP substrate 11 is connected to the lower semiconductor chip 13 and upper semiconductor chip 16 by using bonding wires 17. The MCP substrate 11 is mounted on a motherboard or the like (not shown) by using solder balls 19 that are arranged on the bottom surface of the MCP substrate 11.

The thickness of the MCP module is particularly limited, depending on its specification. It is therefore required that the semiconductor chips to be used in the MCP module should have smaller thicknesses compared to ordinary semiconductor chips. On the other hand, the semiconductor chips in the MCP module must have a sufficient mechanical strength. In view of these requirements, the semiconductor chips to be incorporated in the MCP module are generally 300 μm or less thick, whereas the ordinary semiconductor chips are generally 380 to 430 μm thick. Such a small-thickness semiconductor chip is generally manufactured by forming an element active region in the surface region of a semiconductor substrate, followed by polishing the bottom surface of the semiconductor substrate to a desired thickness for the semiconductor substrate.

In order to make a portable apparatus further smaller and provide the same with a higher operating efficiency, the semiconductor devices provided in the MCP module should have smaller thicknesses so that the MCP module may have a higher integration density. In recent years, the technique for polishing treatment of the semiconductor substrates has advanced. It is now possible to polish semiconductor substrates to a thickness of about 50 μm, substantially without causing any damage on the semiconductor substrates.

If a semiconductor substrate is polished to thickness of 300 μm or less, however, the mechanical strength of the semiconductor chip will decrease. The decrease of mechanical strength results partly from a damage caused by the polishing applied onto the bottom surface of the semiconductor substrate. The semiconductor chip having such a polishing damage may be broken when it receives even a small external impact. To prevent the chip from being broken, a technique is known wherein the bottom surface of the substrate is subjected to a high-precision, mirror-polishing treatment after it has undergone an ordinary rough-polishing treatment, to thereby eliminate the polishing damage resulting from the rough-polishing treatment.

The present inventor has found that any semiconductor chip that has a substrate thickness of about 100 μm or less is far less reliable than semiconductor chips that have a substrate thickness of more than about 100 μm. The present inventor has also found that semiconductor chips having such a small-thickness substrate has a reliability further lowered if the bottom surface of the substrate is subjected to a mirror-polishing treatment. These findings reveal that practical usage of semiconductor devices that have a substrate thickness of about 100 μm or less encounters a large obstacle.

The inventor studied this problem in further detail. It was found that reliability of the semiconductor device decreases because the heavy metals diffuse from the bottom surface of the semiconductor device into the vicinity of the element active region during a heat treatment, after the substrate is polished to have a thickness of about 100 μm or less. It was also found that the decrease in the reliability of the semiconductor device due to the mirror-polishing treatment results from an increase in the amount of heavy metals that diffuse into the vicinity of the element active region, after the polishing damage having a gettering function is eliminated.

The diffusion length “L” over which any particles diffuse in a solid body is generally given by \sqrt{D·t}, where “D” is the diffusion coefficient and “t” is the diffusion time. The diffusion coefficient D is given by D₀^{-Ea/kT}, where D₀ is vibration factor, Ea is activation energy, k is Boltzmann constant and T is absolute temperature. Among other heavy metals, Cu diffuses particularly fast in silicon substrates, and has a vibration factor, D₀, of 3 to 8×10⁻³ cm² per second and an activation energy, EA, of 0.2 to 0.5 eV as is known in the art.

It is assumed herein that a heat treatment is performed in ordinary conditions after the semiconductor chips in the MCP module are completed. Then, the heat treatment may be considered to be carried out at 200 to 300 degrees C. for about 300 to 1000 seconds in total. These numerical values can be applied to find the value of \sqrt{D·t}. The calculation revealed that the diffusion length “L” is about 100 μm.

FIG. 6 shows the vicinity of the lower semiconductor chip shown in FIG. 5 and depicts a situation wherein the heavy metals on the bottom surface of the lower semiconductor chip diffuse into the vicinity of the element active region. The lower semiconductor chip 13 is formed as a DRAM, for example. Upon polishing the bottom surface of the semiconductor chip 13, heavy metals 31 contained in a trace amount in the abrasive compound and the polishing blade may stick onto the bottom surface of the lower semiconductor chip 13. Further, when the lower semiconductor chip 13 is mounted on the MCP substrate 11, the heavy metals 31 contained in a trace amount in the adhesive layer 12 stick onto the bottom surface of the lower semiconductor chip 13. The heavy metals 31 attached onto the chip 13 include Cu, Fe, Zn and the like. It is observed that these heavy metals stick onto the chip 13 in an amount of 50 to 200 atoms/cm².

A heat treatment is carried out at about 150 degrees C. for about 30 minutes in order to achieve thermal curing of the adhesive layers 12 and 15 and the encapsulating resin package 18 (FIG. 5). To achieve re-flow of the solder balls 19, another heat treatment is then performed, for example, at about 280 degrees C. for about 30 seconds. These heat treatments cause the heavy metals 31 to diffuse from the bottom surface of the lower semiconductor chip 13 over a distance of about 100 μm in total. The heavy metals thus diffused reach the depletion layer 32 provided near the element active region 13a and are trapped within crystal defects 31a, if any, in the depletion layer 32. The heavy metals thus trapped have an energy level in the bandgap energy and may become a source of leakage current.

The oxygen-precipitated layers described in Publication Nos. 11-135510 and 11-145146 may be used as gettering layers to control the diffusion of heavy metals into any region near the element active region. The oxygen-precipitated layer exhibits only a relatively small gettering efficiency, although it performs a gettering function if the oxygen concentration is about 10¹⁶/cm³ in the semiconductor substrate. The oxygen concentration may be increased in order to enhance the gettering efficiency of the oxygen-precipitated layer. In this case, however, crystal defects will grow due to the oxygen precipitation as well as due to the conditions of heat treatment, resulting in crystal dislocation. Once crystal dislocation occurs, a large number of voids in the dislocation inevitably promote the diffusion of heavy metals. Consequently, the rigidity of the semiconductor substrate will decrease in some cases.

As described above, it is difficult to use the gettering layer, that is an oxygen-precipitated layer, due to the difficulty of controlling the oxygen concentration during growth of silicon and the conditions of heat treatment. The gettering layer has only a limited gettering efficiency. Further, the thickness thereof is limited in a semiconductor device having a small-thickness substrate. The gettering layer alone can hardly control the diffusion of heavy metals.

### BRIEF SUMMARY OF THE INVENTION

In view of the above problems in the conventional technique, it is an object of the present invention to provide a semiconductor device which is suitable for use as a semiconductor chip in a MCP module, in which heavy metals are prevented from diffusing from the bottom surface into the vicinity of the element active region, and yet which has a higher mechanical strength. It is another object of the present invention to provide a MCP module including such a semiconductor device and a method of manufacturing such a semiconductor device.

The present invention provides a semiconductor device including; a semiconductor substrate having a thickness of not larger than 130 μm; a semiconductor active layer formed in a top surface region of the silicon substrate; and an impurity-doped layer formed between a bottom surface of the semiconductor substrate and the semiconductor active layer, the impurity-doped layer having a thickness not smaller than 50% of a thickness of the semiconductor substrate, the impurity-doped layer having a gettering function for heavy metals.

The present invention also provides a method for manufacturing a semiconductor device for use in a multi-chip-package (MCP) module, including the steps of: forming an active layer in a top surface region of a semiconductor substrate; forming an impurity-doped layer between said active layer and a bottom surface of said substrate; first polishing at said bottom surface of said semiconductor substrate to leave a thickness of not larger than 130 μm for said semiconductor substrate and to obtain a thickness ratio not less than 50% of said impurity-doped layer to said semiconductor substrate; and second polishing at said bottom surface of said semiconductor substrate finely than said first polishing, to obtain a thickness ratio not less than 50% of said impurity-doped layer to said semiconductor substrate; and forming transistors having active regions in said active layer.

In accordance with the semiconductor device of the present invention and a semiconductor device manufactured by the method of the present invention, since the thickness of the impurity-doped layer having a high rigidity is not less than 50% of the thickness of the semiconductor substrate, the resultant semiconductor device has a sufficient mechanical strength even if the semiconductor substrate has a thickness not larger than 130 μm. In addition, since the gettering function of the impurity-doped layer prevents heavy metals from diffusing from the bottom surface of the substrate toward the vicinity of the semiconductor active layer, the resultant semiconductor device has superior transistor characteristics.

The above and other objects, features and advantages of the present invention will be more apparent from the following description, referring to the accompanying drawings.

### BRIEF DESCRIPTION OF THE DRAWINGS

FIG. 1 is a sectional view showing the configuration of an MCP module including a lower semiconductor chip as a semiconductor device according to an embodiment of the present invention;

FIGS. 2A to 2E are sectional views showing consecutively fabrication steps of a method for manufacturing the semiconductor device shown in FIG. 1;

FIG. 3 is a sectional view of a semiconductor device modified from the first embodiment;

FIG. 4 is a sectional view of another semiconductor device modified from the first embodiment;

FIG. 5 is a sectional view depicting the configuration of a conventional MCP module;

FIG. 6 is an enlarged sectional view of the semiconductor device incorporated in the conventional MCP module of FIG. 5;

FIG. 7A is a graph showing the relation between the number of bits and the refresh time, which was observed in the first experiment; and

FIG. 7B is a graph illustrating the relation between the number of defective bits and the substrate thickness, which was observed in the second experiment.

### DETAILED DESCRIPTION OF THE PREFERRED EMBODIMENTS

Before achieving the present invention, the inventor conducted two experiments in order to study the problem that the reliability of semiconductor devices decreases due to the reduction in thickness and the mirror-polishing treatment of the bottom surface of the substrate. In the first experiment, three types of the lower semiconductor chips were fabricated for use in the MCP module 30 shown in FIG. 5. More specifically, several chips of each type were manufactured as the samples for experiments. Each lower semiconductor chip of the samples-1 had a substrate which was 120 a m thick, the bottom surface of the substrate being subjected to a rough polishing treatment. Each lower semiconductor chip of the samsples-2 had a substrate which was 120 μm thick, the bottom surface of the substrate being subjected to both rough polishing and mirror-polishing treatments. Each lower semiconductor chip of the samples-3 had a substrate which was 100 am thick, the bottom surface of the substrate being subjected to both rough polishing and mirror-polishing treatments. These samples of lower semiconductor chips, thus prepared, were incorporated into respective MCP modules 30. The MCP modules were secured onto motherboards, thereby providing samples-1, samples-2 and samples-3 of the MCP modules, corresponding to sampes-1, samsples-2 and samaples-3 of the semiconductor chips. The samples-1, samsples-2 and samples-3 of the MCP modules were tested to determine the relation between the number of bits and the refresh time.

The results of the tests were shown in FIG. 8A, wherein curves-I, -II, and -III represent the results of samples-1, samples-2 and samples-3, respectively. Comparison of samples-1 and samples-2 reveals that the refresh time of the semiconductor devices each having a mirror-polished substrate is shorter than the semiconductor devices each having a rough-polished substrate, although these devices have the same substrate thickness of 120 μm. Further, comparison of samples-2 and samples-3 reveals that the refresh time of the semiconductor devices each having a small-thickness substrate is shorter than the semiconductor devices each having a large-thickness substrate, although these devices have been subjected to both rough-polishing and mirror-polishing treatments. It is to be noted that the impurity-doped layer, after mirror-polishing treatment, had a bottom surface having a center-line surface roughness (Ra) of 5 nm or lower.

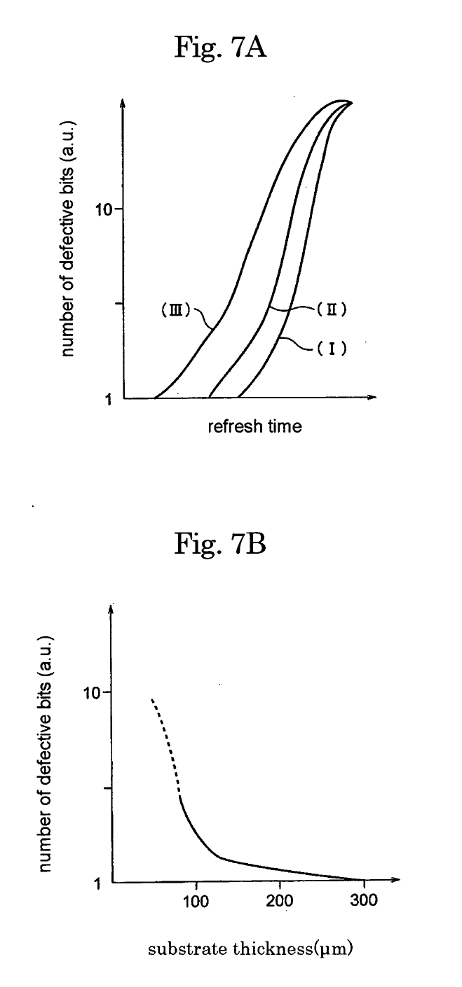

In the second experiment, semiconductor chips were manufactured for use as the lower semiconductor chips in the MCP module 30, each having a substrate different in thickness from one another, the thicknesses of the substrates ranging from 80 to 300 μm. The bottom surface of each semiconductor chip was subjected to both rough-polishing and mirror-polishing treatments. The semiconductor chips, thus manufactured, were incorporated as lower semiconductor chips in the MCP modules 30. The MCP modules were secured to respective motherboards, thereby providing samples-4 that differed from one another in the substrate thickness. These samples-4 were examined for the number of “defective bits”, each having a refresh time shorter than the rated value. The results of the test were shown in FIG. 7B, wherein the solid-line of the curve indicates the actual results of experiment, and the broken-line of the curve shows an estimated value.

From the graph of FIG. 7B, it is evident that the number of defective bits increased as the substrate thickness decreased from 300 μm. At the substrate thickness of about 130 μm, the slope of the curve significantly changed. That is, the number of defective bits abruptly increased at the point corresponding to the substrate thickness of 130 μm. This reveals that the reliability of the chip having a substrate thickness of about 130 μm or less is considerably low, due to the heavy metals diffused from the bottom surface of the lower semiconductor chip. It is to be noted that each of samples-4 had an element active region 13a that was about 20 μm thick.

From the results of the first and second experiments, the inventor has found it necessary to control the diffusion of heavy metals from the bottom surface of a semiconductor chip into the vicinity of the element active region of the chip, if the chip has a substrate thickness of about 130 μm or less.

Any semiconductor device in which the semiconductor substrate is 130 μm or less thick has only an extremely small mechanical strength. It is not preferable that the mechanical stress causes generation of crystal defects in the semiconductor substrate, the crystal defects reducing the rigidity of the semiconductor device. In view of these analyses, the inventor paid attention to the fact that semiconductor layers having a high impurity concentration (heavily-doped layers) decrease the diffusion speed of heavy metals and also have a higher rigidity. As is believed in the art, the reduction of the diffusion speed of the heavy metals is due to the higher density of crystals in the heavily-doped layer wherein a large number of inter-lattice atoms exist in the crystal structure, whereas the higher rigidity is due to the larger number of inter-lattice atoms existing in the layers and resisting against a cleaving force applied thereto.

Namely, the inventor found it effective to form a heavily-doped layer in the substrate of a semiconductor device for reducing the diffusion speed of heavy metals. This prevents the heavy metals from diffusing from the bottom surface of the semiconductor device into the vicinity of the element active region of the device. In this case, the heavy metals would not be a source of leakage current because they have not reached the vicinity of the element active region. In addition, the heavily-doped layer, which has a high rigidity, enhances the mechanical strength of the semiconductor device. It should be noted that the diffusion speed of heavy metals significantly falls if the impurity concentration is 10¹⁸/cm³ or more. A larger fall in the diffusion speed is observed at an impurity concentration of 10²⁰/cm³ or more. The rigidity of any heavily-doped layer increases as the impurity concentration rises.

The inventor conducted another experiment, or the third experiment, on semiconductor devices having a heavily-doped layer that contains impurities at a concentration of 10¹⁸/cm³ or more, in order to determine the relation between the thickness of the heavily-doped layer and the mechanical strength of the device. The results of the third experiment reveal that an external force easily bends or warps the semiconductor device if the thickness of the heavily-doped layer is less than 50% of the thickness of the device. The results also show that the bending or warping of the device can be reliably suppressed if the thickness of the heavily-doped layer is 50% or more, preferably 60% or more, of the thickness of the semiconductor device, to thereby impart sufficient mechanical strength to the semiconductor device.

On the basis of the results of the third experiment, a semiconductor chip according to the present invention includes a semiconductor substrate having a thickness of 130 μm or less and a heavily-doped layer having an impurity concentration of 10¹⁸/cm³ or more and a thickness of 50% or more, preferably 60% or more, of the semiconductor substrate. The semiconductor chip of the present invention has a sufficient mechanical strength. If the substrate thickness of the semiconductor chip is 100 μm or less, the increase in the mechanical strength of the chip will be prominent.

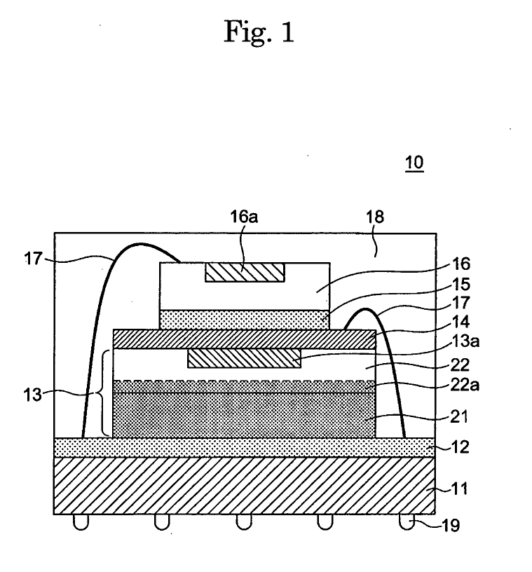

An embodiment of the present invention will be described in detail, with reference to the accompanying drawings. FIG. 1 is a sectional view of an MCP module 10 that includes a semiconductor chip according to the embodiment of the invention. As shown in FIG. 1, the MCP module 10 includes an MCP substrate 11, an adhesive layer 12, a lower semiconductor chip 13, a surface protective film 14, an adhesive layer 15, and an upper semiconductor chip 16. The adhesive layer 12 is provided on the substrate 11. The lower semiconductor chip 13 is mounted on the adhesive layer 12 and has a substrate thickness of about 100 μm or less. The surface protective film 14 and adhesive layer 15 are provided on the lower semiconductor chip 13. The upper semiconductor chip 16 is mounted on the adhesive layer 15.

The lower semiconductor chip 13 is a semiconductor memory device such as a DRAM. The upper semiconductor chip 16 is a semiconductor device other than a DRAM; it may be a CPU, a DSP (Digital Signal Processor), or the like. The adhesive layers 12 and 15 have been prepared by thermally-curing resin paste or tape-shaped layers of resin. The surface protective film 14 is an insulating layer that prevents surface corrosion of the semiconductor device, before the device is incorporated into the MCP module 10.

The MCP substrate 11 includes therein a metallic interconnection pattern, such as made of copper (Cu). The MCP substrate 11, lower semiconductor chip 13 and upper semiconductor chip 16 are connected together by bonding wires 17. The encapsulating resin package 18 is provided on the MCP substrate 11 and encapsulates therein the lower semiconductor chip 13, upper semiconductor chip 16 and bonding wires 17. The MCP substrate 11 has a BGA structure. The MCP module 10 is mounted on a board, such as a motherboard, and is secured thereto by solder balls 19 arranged in the form of an array.

The lower semiconductor chip 13 includes a heavily-doped layer 21 and a lightly-doped layer 22. The heavily-doped layer 21 contains boron at a concentration of 10²⁰/cm³. The lightly-doped layer 22 is disposed on the heavily-doped layer 21 and contains impurities at a relatively low concentration. The heavily-doped layer 21 is about 60 μm thick, measured from the bottom surface of the lower semiconductor chip 13. The thickness of the heavily-doped layer 21 is about 60% of the thickness of the lower semiconductor chip 13.

An element active region 13a that has a P-N junction or the like is formed in the top surface region of the lower semiconductor chip 13. The element active region 13a is formed to the depth of about 20 μm from the top surface of the lower semiconductor chip 13. Boron contained in the heavily-doped layer 21 diffuses into the lightly-doped layer 22, forming an impurity-diffused region 22a. The impurity-diffused region 22a is several micrometers thick. An element active region 16a is formed in the top surface region of the upper semiconductor chip 16.

In the present embodiment, the configuration wherein the heavily-doped layer 21 has a high rigidity and a thickness that is about 60% of that of the lower semiconductor chip 13 imparts a sufficiently large mechanical strength to the lower semiconductor chip 13. In addition, the configuration wherein the thick heavily-doped layer 21 has an impurity concentration as high as 10²⁰/cm³ effectively prevents heavy metals from diffusing from the bottom surface of the lower semiconductor chip 13 into the vicinity of the element active region 13a.

Conventionally, the semiconductor memories incorporated in MCP modules are mainly SRAMs. However, SRAMs are difficult to achieve a higher integration density. Hence, SRAMs are gradually replaced by pseudo-SRAMs (each comprising a DRAM) or dedicated or versatile DRAMs, as the MCP module is required to perform more and more complicated functions. Conventional DRAMs are disadvantageous, however, in that the data-retention capability is greatly influenced by a leakage current. If the semiconductor device according to the present invention is used in a DRAM to be incorporated in a MCP module, it will enhance the data-retention capability of the DRAM.

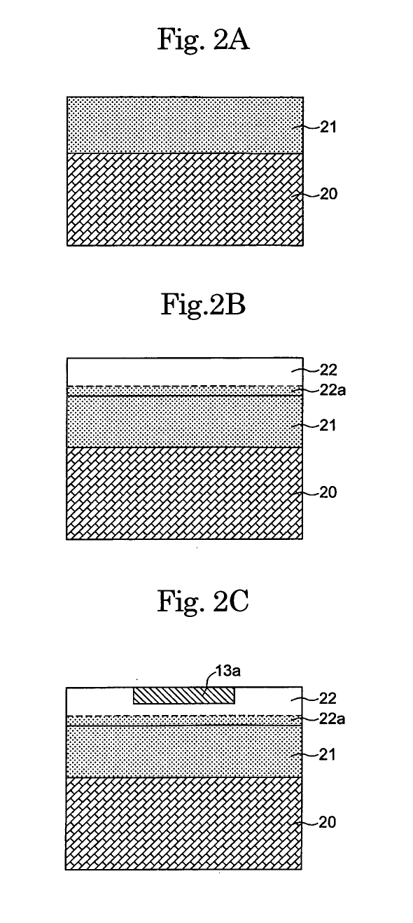

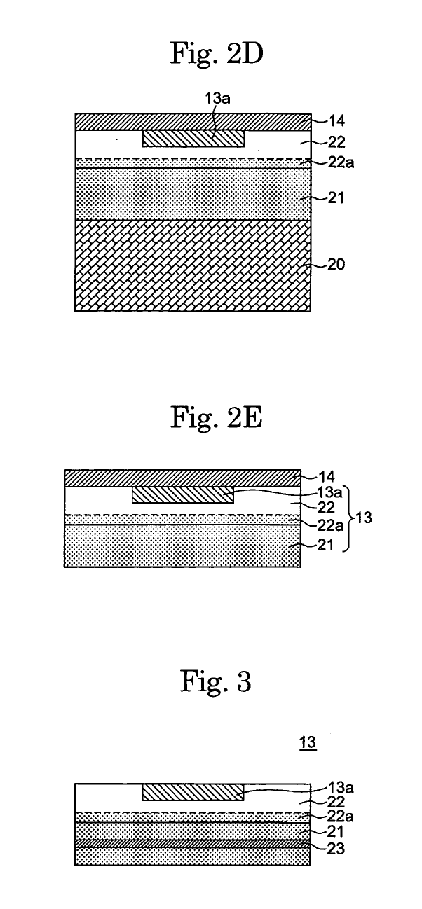

FIGS. 2A to 2E are sectional views showing consecutive steps of a method for manufacturing the lower semiconductor chip 13 having a surface protective film 14 and designed for use in the MCP module 10. First, as shown in FIG. 2A, a silicon layer containing boron at a concentration of 10²⁰/cm³ is formed on a silicon substrate 20 by means of epitaxial growth, to a thickness of, for example, about 100 μm. The thus formed silicon layer constitutes the heavily-doped layer 21 in a semiconductor substrate in the present embodiment.

As shown in FIG. 2B, a silicon layer containing boron at a relatively low concentration is formed on the heavily-doped layer 21, by epitaxial growth, to a thickness of tens of micrometers. The thus formed silicon layer constitutes the lightly-doped layer 22 in the semiconductor substrate in the present embodiment. In or after this step, boron diffuses from the heavily-doped layer 21 into the lightly-doped layer 22. As a result, an impurity-diffused region 22a is formed in the lightly-doped layer 22. The impurity-diffused region 22a is several micrometers thick and contains boron at a relatively high concentration.

As shown in FIG. 2C, impurities are implanted into the top surface region of the silicon substrate 20, thereby forming an element active region 13a. A multi-layer structure, which includes an oxide film and an interconnection layer, is then formed on the top surface of the silicon substrate 20. In these steps, transistors (not shown) and capacitors (not shown, either) are formed. Thereafter, as shown in FIG. 2D, the surface protective film 14 is formed, to cover the silicon substrate 20 including the element active region 13a formed therein. Subsequently, as shown in FIG. 2E, a rough-polishing treatment is performed at the bottom surface of the silicon substrate 20, until the thickness of the silicon substrate 20 decreases to about 100 μm. A part of the silicon substrate 20 including a part of the heavily-doped layer 21 is thereby removed. Then, a mirror-polishing treatment is performed at the bottom surface of the silicon substrate 20, thereby eliminating the scars or scratches resulting from the rough-polishing treatment. Thus, the lower semiconductor chip 13 having the surface protective film 14 on the top surface is completed.

In the method according to the present embodiment, the lightly-doped layer 22 is formed on the heavily-doped layer 21, and the silicon substrate 20 and heavily-doped layer 21 are partly removed, to thereby obtain the lower semiconductor chip 13 for use in the MCP module 10. Although the heavily-doped layer 21 is formed on the silicon substrate 20 in the above embodiment, the heavily-doped layer 21 may be replaced by a bulk silicon substrate that contains impurities at a concentration of 10²⁰/cm³, for example. In such a case, the lightly-doped layer 22 is formed on this silicon substrate by means of epitaxial growth or a similar process, and a rough-polishing treatment is carried out, to thereby remove a part of the silicon substrate and thereby reducing the thickness of the substrate to about 100 μm.

In the present embodiment, the heavily-doped layer 21 can sufficiently enhance the mechanical strength of the lower semiconductor chip 13 by the existence itself of the heavily-doped layer 21. The lower semiconductor chip 13 may have an additional layer that performs a gettering function. The additional layer may be interposed between the element active region 13a and the bottom surface of the lower semiconductor chip 13, may be provided as a part of the heavily-doped layer 21, or may be formed on the exposed surface of the heavily-doped layer 21.

FIG. 3 depicts another lower semiconductor chip, which is a first modified example of the embodiment described above and which has a damaged layer (defective layer). The lower semiconductor chip 13 according to the first modified example is similar to the chip 13 of the above embodiment except that a part of the heavily-doped layer 21 constitutes a damaged layer 23. The damaged layer 23 has crystal defects such as voids. In the first modified example, impurities unevenly distributed around the crystal defects including voids impart a gettering function to the damaged layer 23. Having the gettering function, the damaged layer 23 more efficiently control the diffusion of heavy metals from the bottom surface of the lower semiconductor chip 13 into the vicinity of the element active region 13a.

The method of manufacturing the lower semiconductor chip 13 according to the first modified example is similar to the method of manufacturing the chip 13 of the above embodiment except that oxygen ions, nitrogen ions or the like are implanted into the semiconductor substrate after the step shown in FIG. 2A. The acceleration energy of the ions in the ion-implantation is so controlled to form the damaged layer 23 having an extremely small thickness.

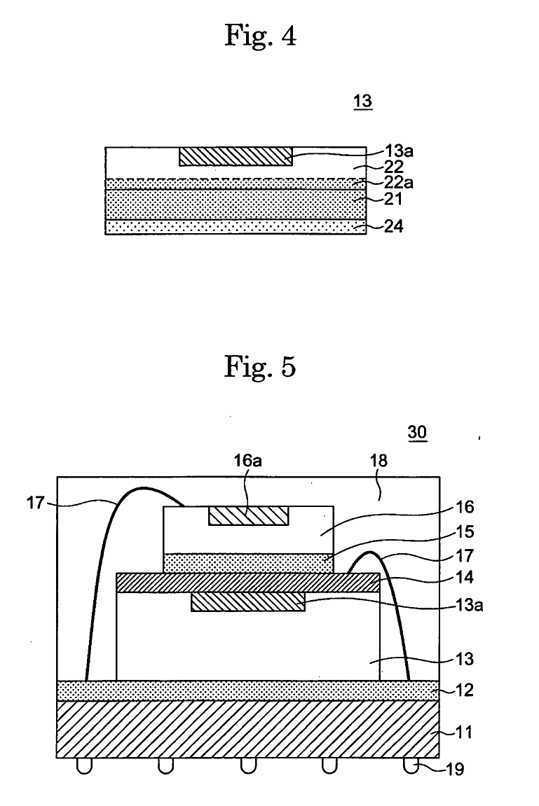

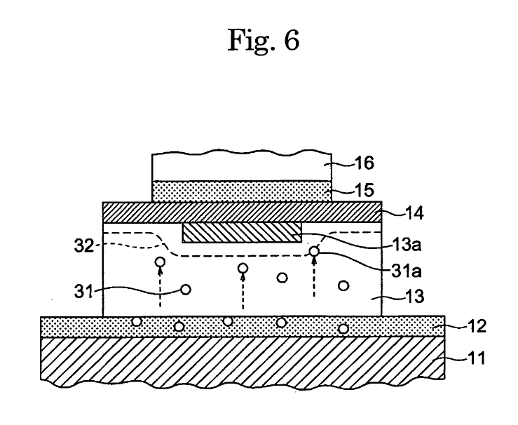

FIG. 4 shows a lower semiconductor chip, which is a second modified example of the embodiment described above and which has an oxygen-precipitated layer. In the lower semiconductor chip 13 of the second modified example, the bottom part of the heavily-doped layer 21 constitutes an oxygen-precipitated layer 24. The heavily-doped layer 21 is about 50 μm thick, and the oxygen-precipitated layer 24 is about 10 μm thick. Except for these features, the lower semiconductor chip 13 is similar in structure to the lower semiconductor chip 13 of the above embodiment. The second modified example achieves advantages similar to those of the first modified example.

A method of manufacturing the lower semiconductor chip 13 of the second modified example will be described. Before performing the step shown in FIG. 2A, the silicon substrate 20 containing oxygen at a high concentration is subjected to a first heat treatment in an inert-gas ambient at a temperature not lower than 1000 degrees C., for example, 1200 degrees C. The first heat treatment removes oxygen from the surface region of the silicon substrate 20. Oxygen should be removed, if the surface region of the silicon substrate 20 contains oxygen at a high concentration, because a large number of defects will develop after another layer is formed on the substrate. The first heat treatment is followed by a second heat treatment, in which the silicon substrate 20 is heated in an inert-gas ambient not higher than 1000 degrees C., for example, 800 degrees C. Inter-lattice oxygen is thereby precipitated, thereby generating a large number of crystal defects.

In the step shown in FIG. 2A, the heavily-doped layer 21 is formed to a thickness of, for example, about 50 μm, by means of epitaxial growth. In the step of FIG. 2E, the rough-polishing treatment is performed at the bottom surface of the silicon substrate 20 until the thickness of the silicon substrate 20 decreases to about 100 μm. In other words, a greater part of the silicon substrate 20 is removed. The remaining part of the silicon substrate 20 is an oxygen-precipitated layer 24. Except for these features, the method of manufacturing the lower semiconductor chip 13 according of the second modified example is similar to the method of manufacturing the chip 13 of the above embodiment. The silicon substrate 20 that contains oxygen at a high concentration may be replaced by a silicon substrate that contains no oxygen similarly to the substrate used in the embodiment. In this case, a silicon layer containing oxygen at a high concentration is formed by epitaxial growth on the silicon substrate and used as the oxygen-precipitated layer 24. If this is the case, the first heat treatment need not be carried out.

In the first and second modified examples as described above, the lower semiconductor chips 13 are designed for use as DRAMs. Nevertheless, the present invention can be applied to semiconductor chips for use in semiconductor devices other than DRAMs, and may be also applied to the upper semiconductor chip 16. The impurities contained in the heavily-doped layer 21 are not limited to boron. The heavily-doped layer 21 may contain other impurities instead, such as phosphorus (P) or the like.

Since the above embodiment and modified examples are described only for examples, the present invention is not limited to the above embodiment and examples and various modifications or alterations can be easily made therefrom by those skilled in the art without departing from the scope of the present invention.

1. A semiconductor device comprising;
a semiconductor substrate having a thickness of not larger than 130 μm;
a semiconductor active layer formed in a top surface region of said silicon substrate; and
an impurity-doped layer formed between a bottom surface of said semiconductor substrate and said semiconductor active layer, said impurity-doped layer having a thickness not smaller than 50% of a thickness of said semiconductor substrate, said impurity-doped layer having a gettering function for heavy metals.

2. The semiconductor device according to claim 1, wherein said thickness of said semiconductor substrate is not larger than 100 μm.

3. The semiconductor device according to claim 1, wherein said thickness of said impurity-doped layer is not smaller than 60% of said thickness of said semiconductor substrate.

4. The semiconductor device according to claim 1, wherein said impurity-doped layer is a silicon layer having an impurity concentration of not less than 10¹⁸/cm³.

5. The semiconductor device according to claim 1, wherein said impurity-doped layer has a bottom surface having a center-line surface roughness (Ra) of smaller than 5 nm.

6. A multi-chip-package (MCP) module comprising a plurality of semiconductor devices including at least one semiconductor device comprising:
a semiconductor substrate having a thickness of not smaller than 130 μm;
a semiconductor active layer formed in a top surface region of said silicon substrate;
an impurity-doped layer formed between a bottom surface of said semiconductor substrate and said semiconductor active layer, said impurity doped layer having a thickness not smaller than 50% of a thickness of said semiconductor substrate, said impurity-doped layer having a gettering function for heavy metals.

7. A method for manufacturing a semiconductor device for use in a multi-chip-package (MCP) module, comprising the steps of:
forming an active layer in a top surface region of a semiconductor substrate;
forming an impurity-doped layer between said active layer and a bottom surface of said substrate;
first polishing at said bottom surface of said semiconductor substrate to leave a thickness of not larger than 130 μm for said semiconductor substrate and to obtain a thickness ratio not less than 50% of said impurity-doped layer to said semiconductor substrate;
second polishing at said bottom surface of said semiconductor substrate finely than said first polishing, to obtain a thickness ratio not less than 50% of said impurity-doped layer to said semiconductor substrate; and
forming transistors having active regions in said active layer.

8. The method according to claim 7, wherein said impurity-doped layer has an impurity concentration of not smaller than 10¹⁸/cm³.
